(19) United States
(12) Patent Application Publication
(10) Pub. No.: US 2007/0020925 A1
(43) Pub. Date: Jan. 25, 2007

(54) METHOD OF FORMING A NICKEL PLATINUM SILICIDE

(76) Inventors: Chao-Ching Hsieh, Hsin-Chu Hsien (TW); Yi-Yiing Chiang, Taipei City (TW); Tzung-Yu Hung, Tainan Hsien (TW); Yi-Wei Chen, Tai-Chung Hsien (TW); Yu-Lan Chang, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/161,075

(22) Filed: Jul. 22, 2005

(51) Int. Cl. H01L 21/44

(52) U.S. Cl. 438/664; 438/682; 438/686

(57) ABSTRACT

A substrate having at least one silicon device is provided. A nickel platinum alloy layer is formed on the substrate. A rapid thermal process is performed to react the nickel platinum alloy layer with the silicon device to produce a nickel platinum silicide. A passivation layer is formed on the nickel platinum silicide followed by using a solution consisting of nitric acid and hydrochloric acid to remove unreacted portions of the nickel platinum alloy layer.

### BACKGROUND OF THE INVENTION

1. Field of the Invention

The present invention relates to a method of forming a silicide, and more particularly, to a method of forming a silicide without leaving platinum residues.

2. Description of the Prior Art

A silicide layer is currently used in the fabrication of metal-oxide-semiconductor (MOS) transistors on a wafer. For example, the silicide layer is often formed on the surface of a gate electrode. The silicide layer provides a good ohmic contact at the interface of the gate electrode and a subsequently formed metal layer, thus reducing resistance of the gate electrode. Among silicide constituents, nickel silicide is considered important to the development of manufacturing processes in the 65 nm MOSFET technology or less because of the characteristics including low electrical resistivity, low silicon consumption, good resistance behavior in narrow lines, and low processing temperature.

A conventional method of forming a nickel silicide includes forming a nickel metal layer on a semiconductor wafer. Then, a first rapid thermal process is performed to react nickel with silicon to produce nickel silicide. Following that, a selective etching process is performed to remove the portions of the nickel metal layer that is not reacted, and a second rapid thermal process is performed to complete the fabrication of the nickel silicide. The reactions in the first and the second rapid thermal processes can be represented by the following equations:
Si+Ni→NiSi
NiSi+Si→NiSi₂

Since the nickel silicide NiSi₂ has low thermal stability, it's possible that nickel may penetrate through the interface between metal and silicon down to the gate electrode to cause spiking effect, or it's possible that nickel may laterally diffuse to the channel region to cause nickel piping effect. To improve the thermal stability of nickel silicide, several approaches have been proposed, such as the use of nickel alloy, especially nickel platinum alloy. Platinum is a noble metal element with stable chemistry properties, and is helpful to improve the thermal stability of nickel silicide. However, platinum also has the property of being difficult to etch, which results in platinum residues issues during the removal of the unreacted metal layer.

Referring to FIG. 1, FIG. 1 is a schematic diagram of platinum residues produced by using a cleaning solution SPM (which is a mixture of sulfuric acid and hydrogen peroxide) to remove unreacted portions of a nickel platinum alloy layer according to the prior art. As shown in FIG. 1, a substrate 10 includes the patterns of a plurality of silicon devices 12, and a silicide 14 composed of nickel platinum alloy and silicon is formed on the silicon devices 12. After the formation of the silicide 14, the prior art method uses the cleaning solution SPM to clean the substrate 10 to selectively etch the unreacted portions of the nickel platinum alloy. Because the cleaning solution SPM can not completely remove platinum, platinum residues 16 left on the substrate 10 can be observed.

To improve the platinum residues issues, the prior art proposes using aqua regia (which is a mixture of nitric acid and hydrochloric acid) to clean the nickel platinum alloy. Referring to FIG. 2, FIG. 2 is a schematic diagram of the removal of unreacted portions of a nickel platinum alloy layer using aqua regia according to the prior art. As shown in FIG. 2, the prior art method deposits a nickel platinum alloy layer on the substrate 10 and performs a first rapid thermal process to react the nickel platinum alloy with silicon to produce the silicide 14. Then, aqua regia is used to clean the surface of the substrate 10. Although aqua regia can remove the unreacted portions of the nickel platinum alloy layer without leaving platinum residues, the silicide 14 is attacked by aqua regia during the cleaning process and a plurality of oxidation regions 18 can be observed forming on the surface of the silicide 14. Since the portions of the silicide 14 in the oxidation regions 18 has unstable resistance, it can not provide good ohmic contact to the silicon devices 12 and reduce the resistance of the silicon devices 12.

### SUMMARY OF THE INVENTION

It is therefore an object of the present invention to provide a method of forming a nickel platinum silicide to prevent the problems of platinum residues and silicide oxidation.

According to one embodiment of the present invention, a substrate having at least one silicon device is provided, and a nickel platinum alloy layer is formed on the substrate. A rapid thermal process is performed to react the nickel platinum alloy layer with the silicon device to produce a nickel platinum silicide. Then, a passivation layer is formed on the nickel platinum silicide followed by using a solution consisting of nitric acid and hydrochloric acid to remove unreacted portions of the nickel platinum alloy layer.

It is an advantage of the present invention that the passivation layer is formed on the nickel platinum silicide, and aqua regia (the mixture of nitric acid and hydrochloric acid) is used to remove the unreacted portions of the nickel platinum alloy layer after the formation of the passivation layer. As a result, the issues of platinum residues and silicide damage caused by a reaction between the aqua regia and the nickel platinum silicide can be effectively prevented.

These and other objects of the claimed invention will be apparent to those of ordinary skill in the art with reference to the following detailed description of the preferred embodiments illustrated in the various drawings.

### BRIEF DESCRIPTION OF THE DRAWINGS

FIG. 1 is a schematic diagram of platinum residues produced by using a cleaning solution SPM to remove unreacted portions of a nickel platinum alloy layer according to the prior art;

FIG. 2 is a schematic diagram of nickel platinum silicide oxidation produced by using aqua regia to remove unreacted portions of a nickel platinum alloy layer according to the prior art

FIGS. 3-7 are schematic diagrams of a method of forming a nickel platinum silicide according to the present invention; and

FIG. 8 is a schematic diagram of a nickel platinum silicide according to the present invention.

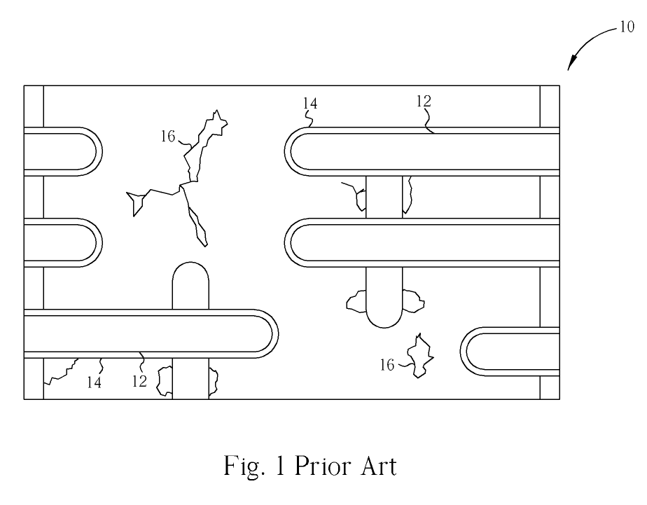

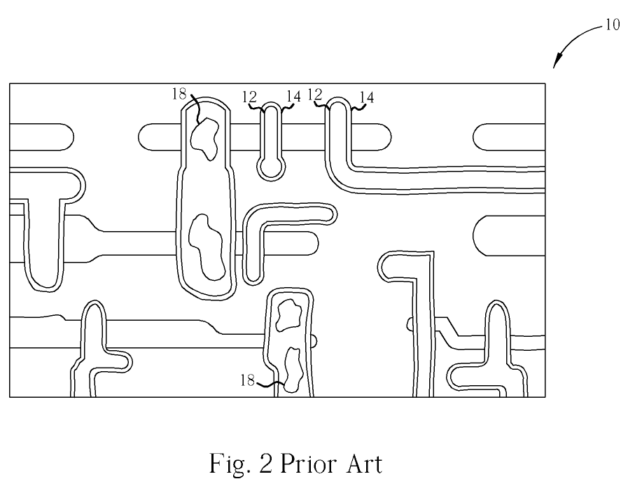

### DETAILED DESCRIPTION

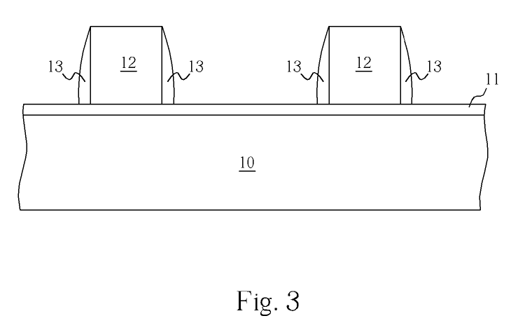

Referring to FIGS. 3-7, FIGS. 3-7 are schematic diagrams of a method of forming a nickel platinum silicide according to the present invention. As shown in FIG. 3, a substrate 10, such as a silicon substrate, is provided. An oxide layer 111 is formed on the substrate 10, at least one silicon device 12, such as a polysilicon gate electrode, is formed on the oxide layer 11, and a spacer 13 is formed on either side of the silicon device 12. In a better embodiment of the present invention, the silicon device 12 is not limited to the gate electrode. The silicon device 12 may include a source/drain region formed on the substrate 10, or include both of the gate electrode and the source/drain region.

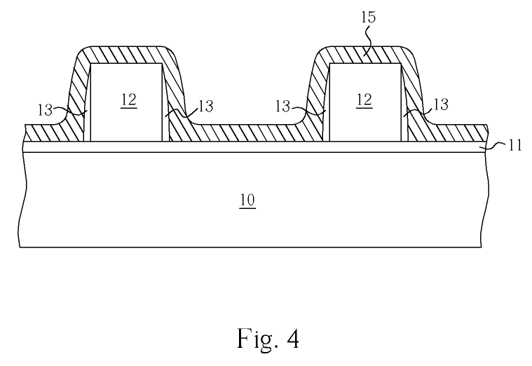

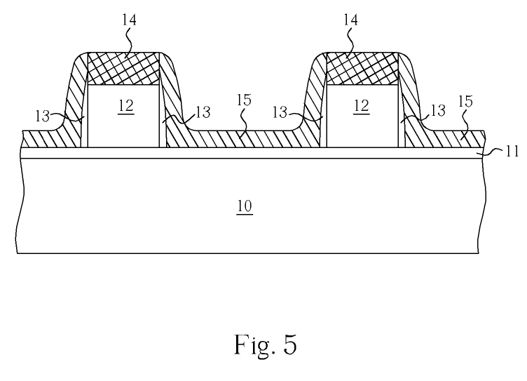

As shown in FIG. 4, an alloy layer 15, such as a nickel platinum alloy layer, is formed on the substrate 10 and contacts to the exposed surface of the silicon device 12. In other embodiments of the present invention, the alloy layer 15 may be other alloy having platinum, and the percentage of platinum in the alloy may be less than 10%. As shown in FIG. 5, a first rapid thermal process is then performed to react metal atoms in the alloy layer 15 with silicon on the silicon device 12 to produce a silicide 14, such as a nickel platinum silicide or other silicide layers having platinum, leaving portions of the alloy layer 15 not reacted on the surfaces of the substrate 10 and the spacer 13.

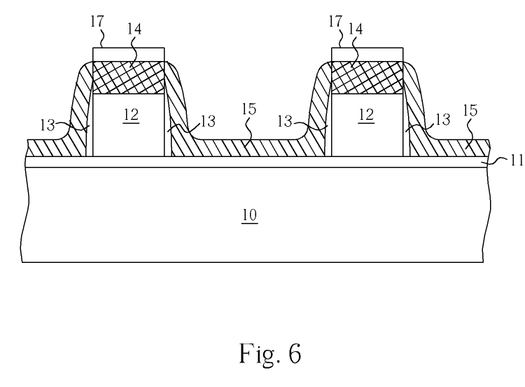

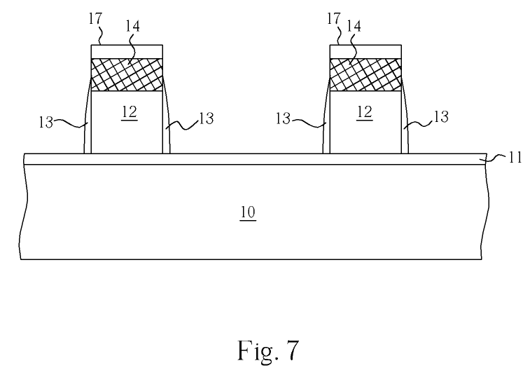

As shown in FIG. 6 and FIG. 7, a passivation layer 17, such as an oxide layer, is formed on the suicide 14, and aqua regia composed of nitrid acid and hydrochloric acid is thereafter used to remove the unreatced or left portions of the alloy layer 15. Since aqua regia can completely remove platinum, no platinum residues will be produced. In addition, the passivation layer 17 is utilized to protect the silicide 14, thus preventing a reaction between the silicide 14 and aqua regia, and preventing oxidation of the silicide 14. In a better embodiment of the present invention, the passivation layer 17 can be formed by using a cleaning solution SPM (i.e. sulfuric acid-hydrogen peroxide mixture), an oxygen plasma, or ozone to provide a surface treatment on the silicide 14. Preferably, a thickness of the passivation layer 17 ranges between about 5 Å and about 40 Å. After the removal of the unreacted alloy layer 15, a second rapid thermal process is performed to reduce resistance of the silicide 14 and complete the formation of the silicide 14.

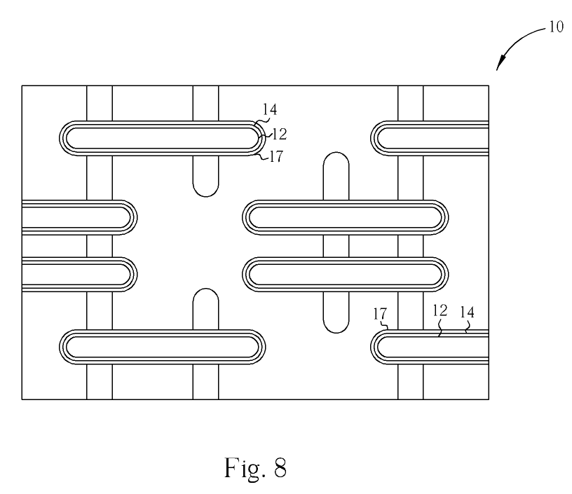

Referring to FIG. 8, FIG. 8 is a schematic diagram of a nickel platinum silicide according to the present invention. As shown in FIG. 8, the passivation 17 is formed on the silicide 14 before the removal of the unreacted portions of the alloy layer 15 utilizing aqua regia, thus preventing the existence of platinum residues and preventing the reaction between aqua regia and the silicide 14 from causing the silicide 14 to be oxidized.

In contrast to the prior art, the method of the present invention improves the uniformity of the nickel platinum silicide and prevents the platinum residues. Therefore, good ohmic contact to the surface of silicon devices including gate electrode and source/drain regions can be provided, and resistance of the silicon devices can be reduced according to the present invention.

Those skilled in the art will readily observe that numerous modifications and alterations of the method may be made while utilizing the teachings of the invention.

What is claimed is:

1. A method of forming a nickel platinum silicide, the method comprising:
providing a substrate, the substrate comprising at least one silicon device;
forming a nickel platinum alloy layer on the substrate;
performing a rapid thermal process to react the nickel platinum alloy layer with the silicon device to produce the nickel platinum silicide;
forming a passivation layer on the nickel platinum silicide; and
using a solution comprising nitric acid and hydrochloric acid to remove unreacted portions of the nickel platinum alloy layer;
wherein the passivation layer protects the nickel platinum silicide and prevents the nickel platinum silicide from reacting with the solution comprising nitric acid and hydrochloric acid.

2. The method of claim 1, wherein the silicon device comprises a gate electrode.

3. The method of claim 1, wherein the silicon device comprises a source/drain region.

4. The method of claim 1, wherein the passivation layer comprises an oxide layer.

5. The method of claim 1, wherein a cleaning solution is utilized to provide a surface treatment on the nickel platinum silicide to form the passivation layer.

6. The method of claim 5, wherein the cleaning solution comprises a mixture of sulfuric acid and hydrogen peroxide.

7. The method of claim 1, wherein an oxygen plasma is utilized to provide a surface treatment on the nickel platinum silicide to form the passivation layer.

8. The method of claim 1, wherein ozone is utilized to provide a surface treatment on the nickel platinum silicide to form the passivation layer.

9. The method of claim 1, wherein a thickness of the passivation layer ranges between 5 Å and 40 Å.

10. A method of preventing platinum residues from a silicide process, the method comprising:
providing a substrate, the substrate comprising at least one silicon device;
forming an alloy layer comprising platinum on the substrate;
performing a first rapid thermal process to react the alloy layer with the silicon device to produce a silicide;
forming a passivation layer on the silicide;
using a solution comprising nitric acid and hydrochloric acid to remove unreacted portions of the alloy layer, so as to prevent the existence of the platinum residues; and
performing a second rapid thermal process;
wherein the passivation layer protects the suicide and prevents the suicide from reacting with the solution comprising nitric acid and hydrochloric acid.

11. The method of claim 10, wherein the alloy layer comprises a nickel platinum alloy.

12. The method of claim 10, wherein the silicon device comprises a gate electrode.

13. The method of claim 10, wherein the silicon device comprises a source/drain region.

14. The method of claim 10, wherein the passivation layer comprises an oxide layer.

15. The method of claim 10, wherein a cleaning solution is utilized to provide a surface treatment on the silicide to form the passivation layer.

16. The method of claim 15, wherein the cleaning solution comprises a mixture of sulfuric acid and hydrogen peroxide.

17. The method of claim 10, wherein an oxygen plasma is utilized to provide a surface treatment on the silicide to form the passivation layer.

18. The method of claim 10, wherein ozone is utilized to provide a surface treatment on the silicide to form the passivation layer.

19. The method of claim 10, wherein a thickness of the passivation layer ranges between 5 Å and 40 Å.
